(19) United States
(12) Patent Application Publication
(10) Pub. No.: US 2006/0141780 A1
(43) Pub. Date: Jun. 29, 2006

(54) Methods for the plasma formation of a microelectronic barrier layer

(76) Inventor: Kenneth C. Cadien, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/022,216

(22) Filed: Dec. 23, 2004

(51) Int. Cl. H01L 21/44

(52) U.S. Cl. 438/656; 438/658; 438/675

(57) ABSTRACT

The fabrication of an interconnect for a microelectronic device through the use of a nitrogen plasma to form a barrier layer. In one embodiment, an opening is formed in a dielectric layer and a metal layer is formed on the sidewalls and bottom of the opening. The metal layer, such as tantalum, is then exposed to nitrogen atoms thereby forming a metal nitride barrier layer.

### BACKGROUND OF THE INVENTION

1. Field of the Invention

An embodiment of the present invention relates to microelectronic device fabrication. In particular, an embodiment of the present invention relates to methods for forming a nitrogen-containing barrier layer for conductive interconnects.

2. State of the Art

The microelectronic device industry continues to see tremendous advances in technologies that permit increased integrated circuit density and complexity, and equally dramatic decreases in package sizes. Present semiconductor technology now permits single-chip microprocessors with many millions of transistors, operating at speeds of tens (or even hundreds) of MIPS (millions of instructions per second), to be packaged in relatively small, air-cooled microelectronic device packages. These transistors are generally connected to one another or to devices external to the microelectronic device by conductive traces and contacts through which electronic signals are sent and/or received.

A typical process of forming traces and contacts includes patterning a photoresist material on a dielectric material and etching the dielectric material through the photoresist material pattern to form a hole and/or a trench (hereinafter referred to collectively as an “opening”) extending into the dielectric material. The photoresist material is then removed (typically by an oxygen plasma) and a barrier layer may be deposit within the opening to prevent conductive material (particularly copper and copper-containing alloys), which will be subsequent be deposited into the opening, from migrating into dielectric material. The migration of the conductive material can adversely affect the quality of microelectronic device, such as leakage current and reliability between the interconnects. A barrier layer is deposited onto a dielectric layer to line the opening. In addition to lining the opening, the barrier layer extends across a top surface of the dielectric layer.

A seed material may then be deposited on the barrier layer, followed by performing a conventional plating process to form a conductive material layer. Like the barrier layer, excess conductive material layer may form on the dielectric layer. The resulting structure is planarized, usually by a technique called chemical mechanical polish (CMP), which removes the copper layer and adhesion layer that are not within the opening from the surface of the dielectric material, to form the interconnect.

Copper has superior conductive properties when used as the conductive material, but is very phone to electomigration. Barrier layers used for copper-containing conductive materials are usually nitrogen-containing materials, including, but not limited to, tantalum nitride and titanium nitride. As the nitrogen-containing barrier layer needs to be a thin as possible, it is generally deposited by an atomic layer deposition (ALD). The conformal step coverage characteristics and thickness control of ALD are preferred for processes that require thin, uniform coverage. ALD relies on self-limiting chemisorption of a reactant molecule (precursor) on targeted deposition surfaces, as will be understood to those skilled in the art.

In one example, an ultrathin ALD nitrogen-containing film may be used as a barrier layer for copper-containing interconnect structures abutting a low-k dielectric material (i.e., any material with a dielectric constant lower than silicon dioxide). As the dimensions of the interconnects are reduced, the nitrogen-containing barrier layer must be very thin (˜10-20 Å) to ensure that the fraction of higher resistivity nitrogen-containing barrier layer is kept to a minimum, such that the overall resistivity of the interconnect remains low.

However, the ALD process to form nitrogen-containing barrier creates volatile by-products, particularly organic amines, ammonia, and 1-methyl-2-pyrrolidone (NMP) (in mere parts per billion) that are generated from the organometallic precursors used in the ALD process, such as pentakis(dimethylamido)tantalum, tert-butylimidotris(diethylamido)tantalum, Ta[NC(CH₃)₂C₂H₅][N(CH₃)₂]₃, and the like, in combination with a reducing agent of ammonia when forming tantalum nitride barrier layer. These volatile by-products can neutralize photoresists, particularly amplified deep-ultraviolet photoresists, including but not limited to poly(t-butylmethacrylate). Such photoresists use a chemical amplification process that is dependent on photogenerated acid produced during the exposure step. The neutralization of the photogenerated acids by the by-products result in the inability to completely develop the exposed photoresist during the lithographic process leaving only the latent image on the wafer, as will be understood to those skilled in the art. This neutralization can occur during the lithographic process from the by-products which can become trapped in the low-k dielectric and diffuse out during the lithographic process, as well as from the by-products which have become airborne contaminants.

Therefore, it would be advantageous to develop apparatus and techniques to form a barrier layer which does not result in the generation of damaging volatile by-products.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings to which:

FIG. 1 is a side cross-sectional view of a dielectric layer having a photoresist patterned thereon, according to the present invention;

FIG. 2 is a side cross-sectional view of the structure of FIG. 1, wherein an opening is formed in the dielectric material layer through the photoresist pattern, according to the present invention;

FIG. 3 is a side cross-sectional view of the structure of FIG. 2, wherein the photoresist is removed, according to the present invention;

FIG. 4 is a side cross-sectional view of the structure of FIG. 3, wherein a metal monolayer is formed adjacent sides and a bottom of the opening, according to the present invention;

FIG. 5 is a side cross-sectional close-up view of inset A of FIG. 4, according to the present invention;

FIG. 6 is a side cross-sectional close-up view of the structure of FIG. 5, wherein the metal monolayer has reacted with nitrogen constituents from a plasma field to form a barrier layer, according to the present invention;

FIG. 7 is a side cross-sectional view of the structure of FIG. 4 after the barrier layer has been formed, according to the present invention;

FIG. 8 is a side cross-sectional view of the structure of FIG. 7, wherein a seed layer is formed over the barrier layer, according to the present invention;

FIG. 9 is a side cross-sectional view of the structure of FIG. 8, wherein a conductive material is disposed within the opening, according to the present invention;

FIG. 10 is a side cross-sectional view of the structure of FIG. 9, wherein a portion of the conductive material not within the opening is remove to form an interconnect, according to the present invention;

FIG. 11 is a side cross-sectional view of barrier layer formation apparatus, according to the present invention; and

FIG. 12 is a side cross-sectional view of another barrier layer formation apparatus, according to the present invention.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

An embodiment of the present invention relates to the fabrication of a barrier layer for a microelectronic device interconnect, wherein the fabrication process utilizes a nitrogen plasma to form the barrier layer.

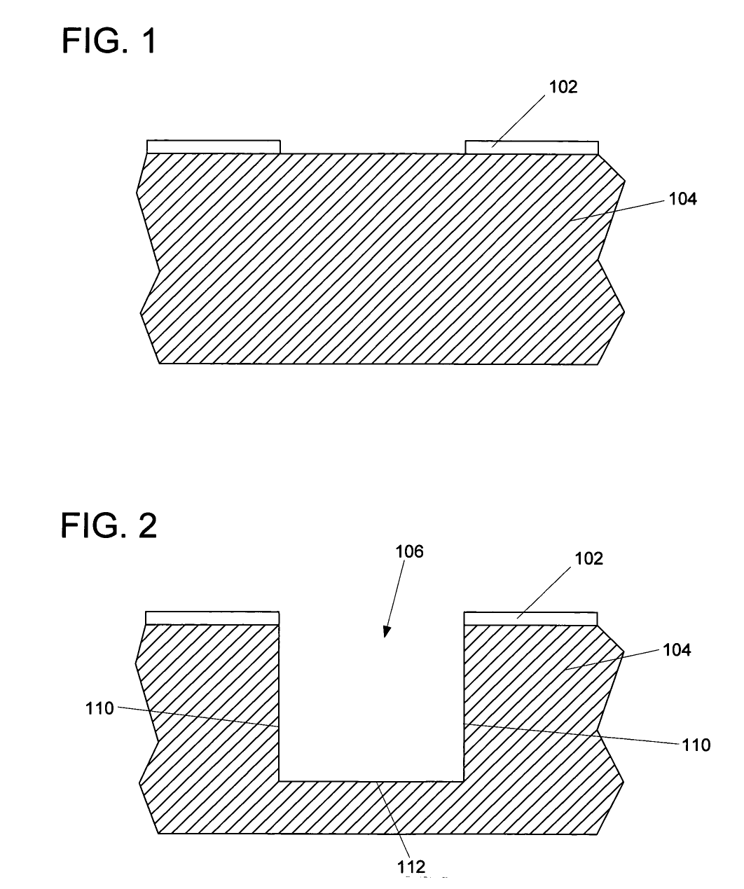

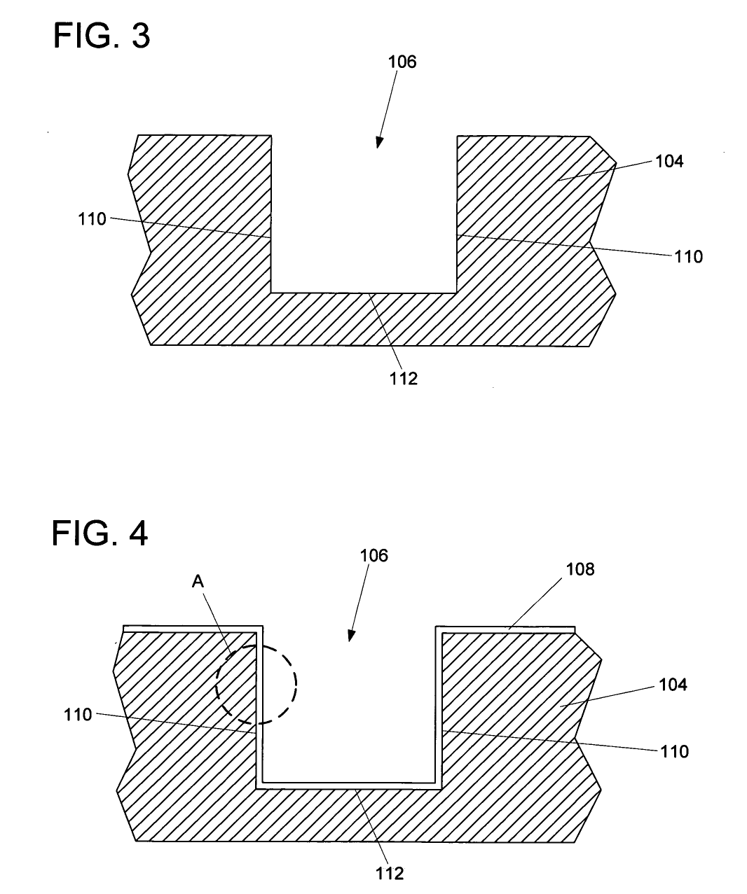

One embodiment of a process used to form an interconnect according to the present invention, comprises patterning a photoresist material 102 on a dielectric material layer 104, as shown in FIG. 1. The dielectric material layer 104 may include, but is not limited to, silicon dioxide, silicon nitride, carbon doped oxide, low-k dielectric, and the like. The dielectric material layer 104 is etched through the photoresist material 102 patterning to form a hole or trench (hereinafter collectively “opening 106”) extending to at least partially through the dielectric material layer 104, as shown in FIG. 2. It is, of course, understood that the opening 106 can be formed by any known technique including, but not limited to, ion milling and laser ablation. The photoresist material 102 is then removed (typically by an oxygen plasma), as shown in FIG. 3.

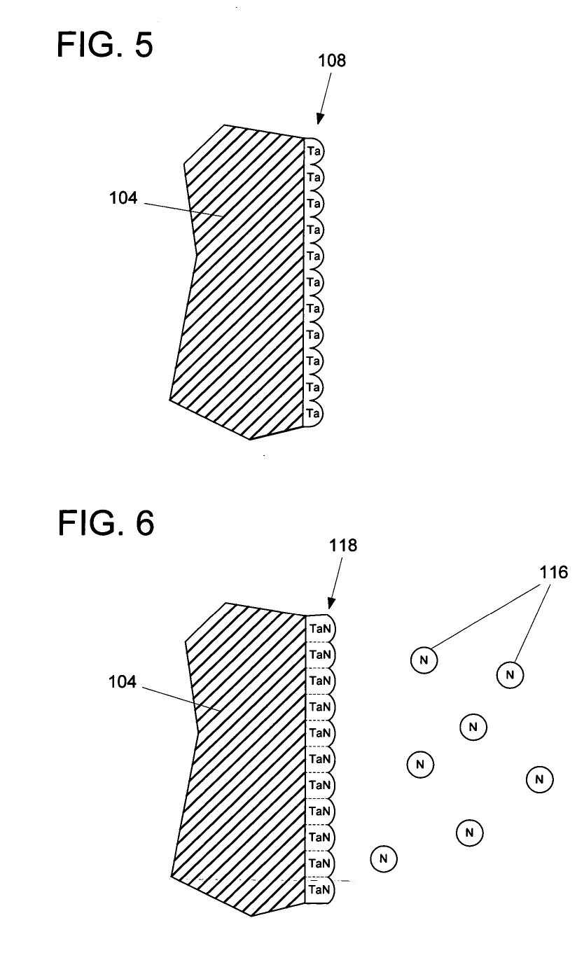

As shown in FIGS. 4 and 5, a metal layer 108, including but not limited to tantalum and titanium, is then formed on sidewalls 110 and a bottom 112 of the opening 106. FIG. 5 illustrates that the metal layer 108 as tantalum (Ta), but the present invention is not so limited. The metal layer 108 may be substantially a monolayer (i.e., substantially one atom thick). A portion of the metal layer 108 also extends over and abuts a first surface 114 of the dielectric material layer 104. The metal layer may be deposited by any ALD technique known in the art.

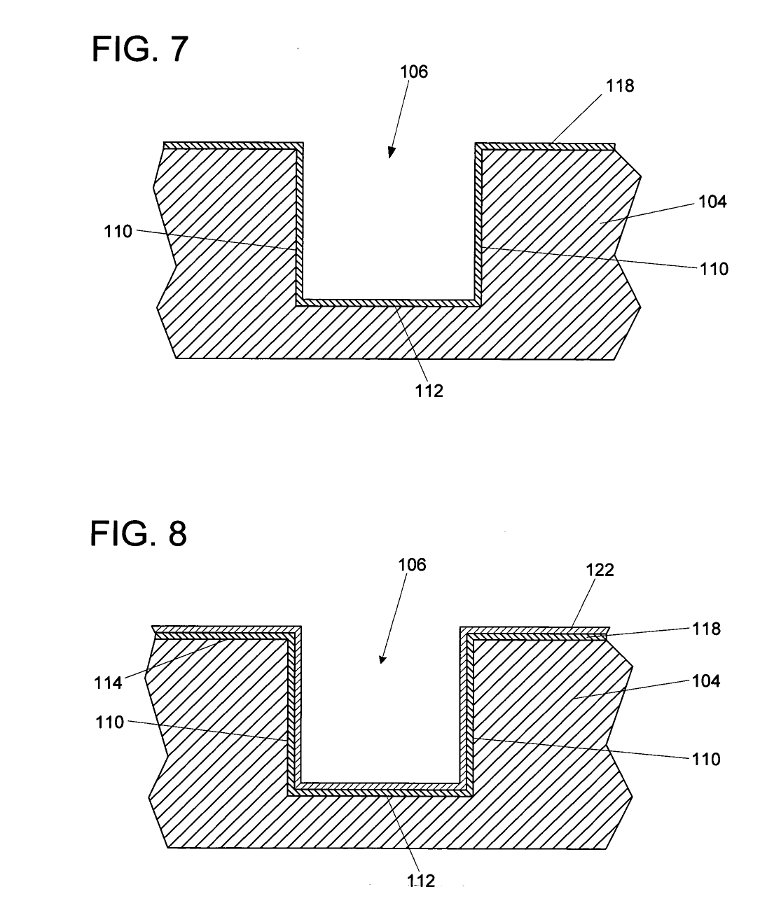

The metal layer 108 (FIG. 5) is then exposed to nitrogen atoms 116 (FIG. 6). Nitrogen in an atomic state is highly reactive and reacts with the metal layer 108 to form a nitrided barrier layer 118, as shown in FIGS. 6 and 7. In FIG. 6, for illustrative purposes, the nitrided barrier layer 118 is tantalum nitride (TaN) and, in one embodiment, the exposure to the nitrogen atoms 116 is timed to form a stoichiometric, monolayer TaN barrier layer 118.

The nitrogen atoms 116 are preferably generated by a nitrogen plasma. Nitrogen plasmas are very stable and long-lived and, thus, can be located remotely from the target where the reaction occurs. Nitrogen plasmas essentially split nitrogen gas into reactive species, including nitrogen atoms, nitrogen ions, and metastable or excited nitrogen molecules. These nitrogen plasmas are free of amines and, thus, do not pose a threat of photoresist poisoning, as discussed above. The nitrogen atoms 116 needed to form the nitrided barrier layer 118 are generated in concentrations which are several orders of magnitude greater than the concentration of the other species generated in the plasma field. Therefore, the other species generated in the plasma will have an insignificant impact on the formation of the stoichiometric TaN barrier layer 118.

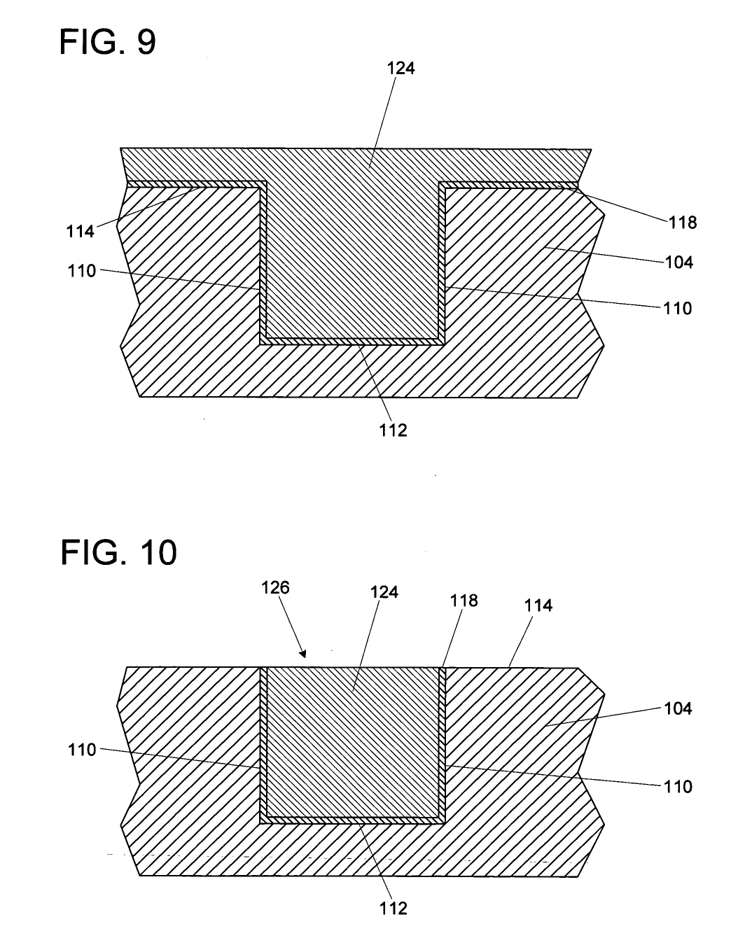

As shown in FIG. 8, a seed material 122 may be deposited on the nitrided barrier layer 118 by any method known in the art. The opening 106 (FIG. 8) is then filled with the conductive material, such as copper, aluminum, alloys thereof, and the like, as shown in FIG. 9, to form a conductive material layer 124. The conductive material layer 124 may be formed by any known process, including but not limited to electroplating, deposition, and the like. The resulting structure is planarized, usually by a technique called chemical mechanical polish (CMP), which removes any portion of the conductive material layer 124 and nitrided barrier layer 118 that is not within the opening 106 (FIG. 8) from the dielectric material layer first surface 114, to form an interconnect 126, as shown in FIG. 10.

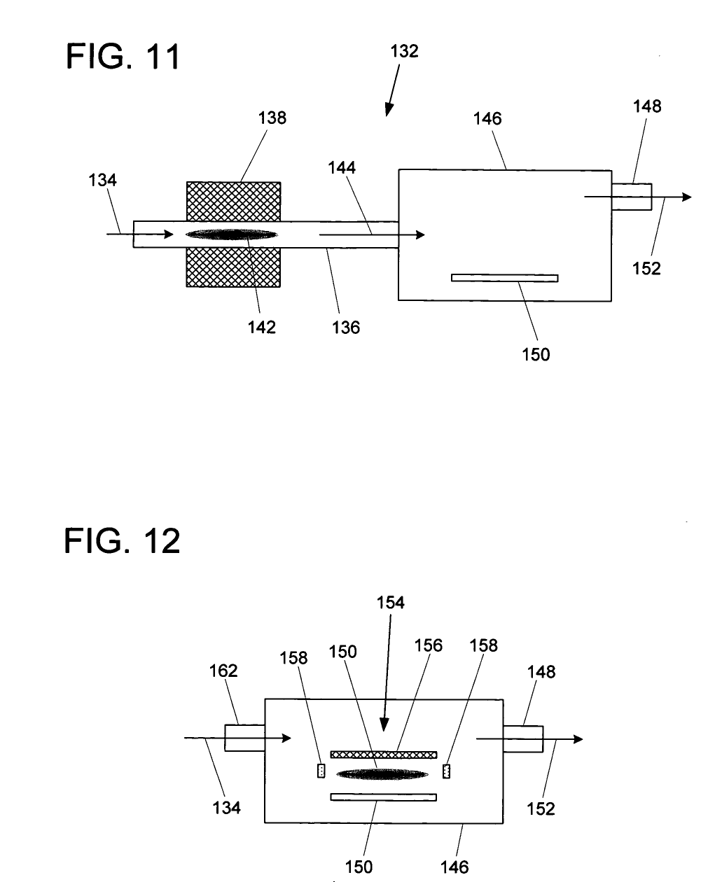

Referring back to the plasma process in the formation of the nitrided barrier layer 118, as the nitrogen atom concentration remains relatively constant away from or downstream from the plasma field, a suitable ALD reactor 132 could be designed to incorporate a remote nitrogen plasma source, as shown in FIG. 11. An inflow nitrogen gas (illustrated as arrow 134) flows into a conduit 136, such as a silica tube. The conduit 136 delivers the nitrogen gas 134 into a plasma generator 138, such as a microwave generator, wherein the nitrogen gas 134 is converted in nitrogen atoms and other reactive species, as previously discussed, as a nitrogen plasma 142. The nitrogen atoms and other reactive species (illustrated as arrow 144) generated in the nitrogen plasma 142 flow down the conduit 136 to a reaction chamber 146. The reaction chamber 146 houses a target 150, which has at least one dielectric material layer 104 having an opening 106 and a metal layer 108 therein, as previously discussed and shown in FIG. 4. Excess gas and reactive species 152 may be exhausted from an outlet 148.

It is, of course, understood that the nitrogen plasma 142 may be struck proximate the target 150. As shown in FIG. 12, a plasma generator 154 may comprise a radio frequency (RF) source 156, with either an electrode plate (capacitive coupling) or a coil (inductive coupling)

158. The RF source 156 creates an RF field within the nitrogen gas in the reaction chamber 146 delivered through an inlet 162, and this coupling creates the nitrogen plasma 142.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method of fabricating a barrier layer, comprising:
providing a dielectric layer;
forming a metal layer abutting said dielectric layer; and
exposing said metal layer to nitrogen atoms.

2. The method of claim 1, wherein forming a metal layer comprises forming a tantalum layer.

3. The method of claim 2, wherein forming said tantalum layer comprises forming a substantially monolayer tantalum layer.

4. The method of claim 3, wherein exposing said substantially monolayer tantalum layer to nitrogen atoms substantially forms a tantalum nitride monolayer.

5. The method of claim 1, further including striking a nitrogen plasma to form said nitrogen atoms.

6. The method of claim 1, wherein providing a dielectric layer comprises providing a low-k dielectric material.

7. A method of fabricating an interconnect, comprising:
flowing nitrogen gas to a plasma generation device;
striking a nitrogen plasma within said plasma generation device to form nitrogen atoms from a nitrogen-containing gas; and
delivering said nitrogen atoms to a metal layer on a dielectric material, wherein said nitrogen atoms react with said metal layer to form a metal nitride barrier layer.

8. The method of claim 7, wherein delivering said nitrogen atoms to said metal layer comprises delivering said nitrogen atoms to a tantalum layer.

9. The method of claim 8, wherein delivering said nitrogen atoms to said tantalum layer comprises delivering said nitrogen atoms to a substantially monolayer tantalum layer.

10. The method of claim 9, wherein delivering said nitrogen atoms to said substantially monolayer tantalum layer to nitrogen atoms substantially forms a tantalum nitride monolayer.

11. The method of claim 7, wherein delivering said nitrogen atoms to a metal layer on a dielectric material comprises delivering said nitrogen atoms to a metal layer on a low-k dielectric material.

12. A method of fabricating an interconnect, comprising:
providing a dielectric layer having an opening defined therein by at least one sidewall and a bottom surface;
forming a metal layer on said at least one sidewall and said bottom surface; and
exposing said metal layer to nitrogen atoms.

13. The method of claim 12, further comprising disposing a conductive material within said opening after exposing said metal layer to nitrogen atoms.

14. The method of claim 13, wherein forming a metal layer comprises forming a tantalum layer.

15. The method of claim 14, wherein forming said tantalum layer comprises forming a substantially monolayer tantalum layer.

16. The method of claim 15, wherein exposing said substantially monolayer tantalum layer to nitrogen atoms substantially forms a tantalum nitride monolayer.

17. The method of claim 12, further including striking a nitrogen plasma to form said nitrogen atoms.

18. The method of claim 12, wherein providing a dielectric layer comprises providing a low-k dielectric material.
